(19) United States
(12) Patent Application Publication
(10) Pub. No.: US 2005/0098906 A1
(43) Pub. Date: May 12, 2005

(54) Source gas flow control and CVD using same

(75) Inventors: Kiyoshi Satoh, Tokyo (JP); Hak Ju Lee, Tokyo (JP); Tomohisa Nishikawa, Tokyo (JP); Akira Sasaki, Tokyo (JP); Masahiro Nanbu, Tokyo (JP)

Correspondence Address: KNOBBE MARTENS OLSON & BEAR LLP, 2040 MAIN STREET, FOURTEENTH FLOOR, IRVINE, CA, 92614, US

(73) Assignees: ASM JAPAN K.K., Tokyo (JP); ADVANCED ENERGY JAPAN K.K., Tokyo (JP)

(21) Appl. No.: 10/928,517

(22) Filed: Aug. 27, 2004

(30) Foreign Application Priority Data
Aug. 28, 2003 (JP) 2003-304501

(51) Int. Cl. C01B 17/22; F02M 1/00; F24F 3/14; C10K 1/08; C23C 16/00; H01L 21/66

(52) U.S. Cl. 261/19; 118/725; 118/715; 261/69.1; 438/14; 438/758; 438/584; 427/249.15; 261/66

(57) ABSTRACT

A source-gas supply apparatus for supplying a source gas into a CVD reactor includes: a reservoir for storing a liquid material; a gas flow path connected the reservoir and the CVD reactor; a sonic nozzle disposed in the gas flow path, through which the source gas is introduced into the CVD reactor; a pressure sensor disposed in the gas flow path upstream of the sonic nozzle; a flow control valve disposed in the gas flow path upstream of the pressure sensor; and a flow control circuit which receives a signal from the pressure sensor and outputs a signal to the flow control valve to adjust opening of the flow control valve as a function of the signal from the pressure sensor.

### BACKGROUND OF THE INVENTION

1. Field of the Invention

The present invention generally relates to a plasma CVD apparatus for forming a thin film on a semiconductor substrate or a glass substrate; and particularly to an apparatus for supplying a reaction gas gasified from a liquid material used for film formation.

2. Description of the Related Art

In recent years, copper having smaller electric resistance has been adopted as a metal wiring material in order to make LSI devices faster, and carbon-containing silicon oxide films having low dielectric constants have been adopted as insulation films between lines in order to reduce capacitance between lines, which causes signal delays. In a method for forming these carbon-containing silicon oxide films, an alkoxysilicon compound having a silane structure is used as a source material in order to form films having a given structure: In the above, the term “carbon-containing silicon oxide films” used herein is used synonymously with “oxygen-containing silicon carbide films.” Consequently, a description of carbon-containing silicon oxide films covers oxygen-containing silicon carbide films; conversely, a description of oxygen-containing silicon carbide films covers carbon-containing silicon oxide films.

Additionally, barrier films used for copper diffusion prevention are being changed from silicon nitride films (with dielectric constants of approximately 7) to silicon carbide films (with dielectric constants of 4-5). In order to form these silicon carbide films, alkylsilicon compounds having silicon-carbon bonds in a molecule are used as source materials.

These alkoxysilicon compounds and alkylsilicon compounds are liquid at room temperature and at atmospheric pressure. In order to form respective films on semiconductor substrates, supplying them in gas phase into a reaction chamber is necessary.

As a system for gasifying and supplying conventional liquid substances, there is a method for getting them out as gases by increasing a vapor pressure of the liquid substances by heating a tank storing them and controlling the gases at a given flow rate by a mass flow controller (for example, Japanese Patent Laid-open No. 1994-256036).

As another method, there is a direct gasification method which gasifies a liquid or a mixture of a liquid and an inert gas by directly heating it and simultaneously control its flow rate by a flow control valve (for example, Japanese Patent Laid-open No. 2001-148347, Japanese Patent Laid-open No. 2001-156055, and U.S. Pat. No. 5,630,878).

In these two types of gasified flow rate control methods, liquid source materials are heated by a heater; at the same time, a gas flow rate is detected by a mass flowmeter provided at a rear step of the flow control valve. By automatically comparing flow signal values detected and flow preset signal values for film formation, a flow control circuit adjusts a gate of the flow control valve so as to match these values.

Conventionally, for forming silicon oxide films used for insulation films between lines in LSI devices, TEOS or SiH₄ has been used as a reaction source gas. SiH₄ is gaseous at normal temperature and at atmospheric pressure and is supplied as a source gas by a cylinder; its flow rate can be controlled with high precision by a general gas mass flow controller. TEOS is liquid at normal temperature and at atmospheric pressure and is supplied into a reaction chamber after it is gasified by any one of the above-mentioned methods and its flow rate is controlled as a gas.

Because the above-mentioned alkoxysilicon compound or alkylsilicon compound is liquid at normal temperature and at atmospheric pressure, it is required to supply the compound into the reaction chamber as a gas in order to form a film on a semiconductor substrate. These compounds, however, have high vapor pressure as compared with TEOS and a boiling point in the range of 20-100° C. This relatively low boiling point means that the vapor characteristic of these compounds lies midway between high-pressure gases such as SiH₄ and liquid source materials such as TEOS. If conventional gasifiers and gas mass flowmeters are used, the following problems occur.

The first problem is that supply pressure becomes insufficient due to vapor pressure drop. When a reaction source material which is liquid at room temperature is stored in an airtight tank and is taken out from the upper room of the airtight tank as a gas and a gas flow rate is controlled by a single gas flow controller, a temperature of the reaction gas drops as it is supplied because heat is lost by latent heat of its own gasification. Due to this temperature drop, a vapor pressure of the reaction gas also drops. Even with a flow controller having a heating device, a pressure of the reaction gas being supplied to the flow controller drops by latent heat generated by gasification of the liquid source material with the start of supplying the reaction gas, causing malfunction of a flow control valve or a flow error of a thermal type flowmeter disposed inside the flow controller due to pressure change of the reaction gas. Because thermal type flowmeters detect a flow rate of a gas running inside them from heat conduction of the gas, changes are detected as flow rate errors if gas pressure changes and heat capacity is changed. If a tank storing the liquid source material is heated intensively to prevent a vapor pressure of the liquid source material from dropping, in the case of an alkoxysilicon compound or alkylsilicon compound having a relatively low boiling point, gasification occurs from within the liquid in addition to gasification from its surface, and it comes to the boil. This boiling causes an uncontrollable change in a pressure of a gas taken out, blocking stable flow rate control by a mass flow controller. This unstable flow rate control and a flow rate with an error cause serious problems in film formation onto a semiconductor substrate. If a flow rate of the reaction gas is deviated from a design value, a thickness and quality of a thin film formed are deviated from design values, causing malfunction of LSI devices. Additionally, if flow rate control becomes unstable, plasma discharge becomes unstable, forming an uneven film or generating abnormally discharge.

The second problem is that a more serious uncontrollable flow rate situation occurs if a direct gasifier which gasifies a liquid directly is used. Alkoxysilicon or alkylsilicon compounds have high vapor pressure and their boiling points are in the range of 20-100° C. In a direct gasification method, because a liquid is forcibly gasified by directly heating it by a flow control valve, the liquid is gasified in portions having high temperature in addition to a gasification portion for which a flow rate is controlled; gas generated in the portions other than the gasification portion causes rapid pressure fluctuations to the flow control valve, hindering stable gasification and flow rate control. If gasification/flow rate control is executed in this state, the gasified reaction gas with pulsation is fed from the gasified gas flow controller to the reaction chamber, creating unstable gas concentration in a film formation area in which a semiconductor substrate is placed. This unstable gas concentration causes plasma discharge blinking or arc discharge, generating particles in a reaction space or abnormal film growth.

### SUMMARY OF THE INVENTION

Consequently, in an aspect, an object of the present invention is to provide a source-gas supply apparatus for stably supplying a liquid source material having a relatively low boiling point to a reaction chamber after gasifying the liquid source material.

In another aspect, an object of the present invention is to form carbon-containing silicon oxide films, nitride-containing silicon carbide films or silicon carbide films having low dielectric constants using the above-mentioned source-gas supply apparatus.

In still another aspect, an object of the present invention is to provide a plasma CVD apparatus capable of performing thin-film formation processing onto a semiconductor substrate repeatedly with excellent reproducibility.

The present invention can accomplish one or more of the above-mentioned objects in various embodiments. However, the present invention is not limited to the above objects, and in embodiments, the present invention exhibits effects other than the objects.

In an aspect, the present invention provides a source-gas supply apparatus for supplying a source gas into a CVD reactor, which comprises: (i) a reservoir for storing a liquid material having an inlet port through which the liquid material is introduced and an outlet port through which a source gas gasified from the liquid material is discharged, said reservoir being provided with a heater; (ii) a gas flow path connected the reservoir and the CVD reactor; (iii) a sonic nozzle disposed in the gas flow path, through which the source gas is introduced into the CVD reactor; (iv) a pressure sensor disposed in the gas flow path upstream of the sonic nozzle; (v) a flow control valve disposed in the gas flow path upstream of the pressure sensor; and (vi) a flow control circuit which receives a signal from the pressure sensor and outputs a signal to the flow control valve to adjust opening of the flow control valve as a function of the signal from the pressure sensor.

The above embodiment includes, but is not limited to, the following embodiments:

The flow control circuit may include a feedback control system which adjusts the opening of the flow control valve to maintain a set-point mass flow rate based on the detected pressure. In an embodiment, a relationship between the detected pressure and the mass flow rate under estimated conditions is predetermined, and based on the relationship, the flow control circuit determines the mass flow rate from the detected pressure and controls the flow control valve as a function of the determined mass flow rate in order to maintain the set-point mass flow rate. In another embodiment, the flow control circuit controls the flow control valve simply as a function of the detected pressure. Any other suitable control methods can be used wherein the flow control circuits outputs a signal as a controlled variable to adjust the opening of the flow control valve.

The source-gas supply apparatus may further comprise a housing which encloses the reservoir, the sonic nozzle, the pressure sensor, and the flow control valve.

The source-gas supply apparatus may further comprise a temperature controller, wherein the housing is provided with a temperature sensor, and the temperature controller controls the temperature inside the housing.

The source-gas supply apparatus may further comprise a temperature controller, wherein the reservoir includes a temperature sensor, and the temperature controller controls the temperature inside the reservoir.

The gas flow path may further comprise a shutoff valve downstream of the sonic valve and a shutoff valve upstream of the flow control valve.

The reservoir may contain an alkoxysilicon compound or an alkylsilicon compound.

The gas flow path may be enclosed by a heating element.

In another aspect, the present invention provides a CVD apparatus comprising: (I) a reactor for forming a thin film on a semiconductor substrate; (II) any source-gas supply apparatus of the foregoing which is connected to the reactor; and (II) an additive gas supply apparatus connected to the reactor, to supply an additive gas into the reactor.

The above embodiment includes, but is not limited to, the following embodiments:

The CVD apparatus may further comprise a radio-frequency (RF) oscillator to supply RF power to the reactor.

The source-gas supply apparatus may further comprise a housing which encloses the reservoir, the sonic nozzle, the pressure sensor, and the flow control valve.

The gas flow path between the reactor and the housing may be enclosed by a heating element.

In still another aspect, the present invention provides a method for controlling a source gas flow, comprising: (a) storing a liquid material in a reservoir; (b) gasifying the liquid material in the reservoir to produce a source gas; (c) passing the source gas through a sonic nozzle to feed the source gas into a CVD reactor; (d) detecting a pressure upstream of the sonic nozzle; and (e) if the detected pressure does not correspond to a set-point flow rate, adjusting flow of the source gas upstream of the sonic nozzle to maintain the flow at the set-point flow rate.

The above embodiment includes, but is not limited to, the following embodiments:

A pressure upstream of the sonic nozzle may be set at least twice a pressure downstream of the sonic nozzle, so that the source gas can flow through the sonic nozzle effectively at sonic speed.

An environment surrounding the sonic nozzle may be controlled at a pre-selected temperature.

The reservoir may be controlled at a pre-selected temperature.

The liquid material may have a boiling point in the range of about 20° C. to about 100° C.

The liquid material may be an alkoxysilicon compound or an alkylsilicon compound.

In yet another aspect, the present invention provides a method for controlling a source gas flow, comprising: (a) storing an alkoxysilicon compound or an alkylsilicon compound as a liquid material in a reservoir; (b) gasifying the liquid material in the reservoir to produce a source gas; (c) passing the source gas through a sonic nozzle to feed the source gas into a chamber; (d) detecting a pressure upstream of the sonic nozzle; and (e) if the detected pressure does not correspond to a set-point flow rate, adjusting flow of the source gas upstream of the sonic nozzle to maintain the flow at the set-point flow rate.

In an additional aspect, the present invention provides a method of thin film formation, comprising: (A) supplying the source gas into a reactor by any method of the foregoing; (B) supplying an additive gas into the reactor; and (C) forming a thin film on a semiconductor substrate placed in the reactor by CVD.

The above embodiment includes, but is not limited to, the following embodiments:

The method may further comprise supplying radio-frequency (RF) power to the reactor.

The additive gas may be an inert gas. The additive gas may be an inert gas and ammonia. The additive gas may be an inert gas and carbon dioxide, oxygen or N₂O.

The thin film may be a silicon carbide film.

The liquid material may be tetramethylsilane or dimethyldimethoxysilane.

In all of the aforesaid embodiments, any element used in an embodiment can interchangeably be used in another embodiment unless such a replacement is not feasible or causes adverse effect. Further, the present invention can equally be applied to apparatuses and methods.

In at least one embodiment of the present invention, a gas flow rate can be maintained to be constant even if a source gas pressure is changed, and hence stable control of gas supply can be ensured.

Additionally, in at least one embodiment of the present invention, silicon carbide films having dielectric constants of 4.0-5.0 (3.0 or less when dimethyldimethoxysilane, DMDMOS, is used as a source gas) and film-thickness non-uniformity of ±3% or less can be formed at a rate of 100 nm/min. or faster.

Furthermore, in at least one embodiment of the present invention, reproducibility of a film thickness at the time of consecutive film formation on 1000 pieces of substrates can be ±0.99%; and excellent reproducibility can be achieved.

For purposes of summarizing the invention and the advantages achieved over the related art, certain objects and advantages of the invention have been described above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

Further aspects, features and advantages of this invention will become apparent from the detailed description of the preferred embodiments which follow.

### BRIEF DESCRIPTION OF THE DRAWINGS

These and other features of this invention will now be described with reference to the drawings of preferred embodiments which are intended to illustrate and not to limit the invention.

FIG. 1 is a schematic is a schematic diagram of the plasma CVD apparatus according to an embodiment of the present invention.

FIG. 2 is an enlarged schematic diagram of the source-gas supply apparatus according to an embodiment of the present invention.

FIG. 3 shows consecutive film formation test results of silicon carbide films.

FIGS. 4(a) and (b) show flow rate controllability of the source-gas supply apparatus according to an embodiment of the present invention.

FIG. 5 is a diagram showing the principle of mass flow determination.

Explanation of symbols used is as follows: 1: Plasma CVD apparatus; 2: Reaction chamber; 3: Susceptor; 4: Showerhead; 5: Exhaust port; 6: Grounding; 7: Matching circuit; 8: Radio-frequency oscillator; 9: Semiconductor substrate; 10: Piping; 11: Valve; 12: Junction; 13: Heater; 14: Piping; 15: Piping; 16: Valve; 17: Flow controller; 18: Piping; 19: Piping; 20: Heater; 21: Housing; 22: Liquid tank; 23: Flow controller; 24: Inlet port; 25, 26: Valve; 27: Liquid source material; 28: Temperature sensor; 29: Temperature controller; 30: Heater; 31: Piping; 32: Conductance regulating valve; 33: Temperature sensor; 34: Temperature controller; 35: Heater; 37: Valve; 41: Flow control valve; 42: Pressure sensor; 43: Flow control circuit; 44: Electric signal terminal; 45: Sonic nozzle.

### DETAILED DESCRIPTION OF THE PREFERRED EMBODIMENT

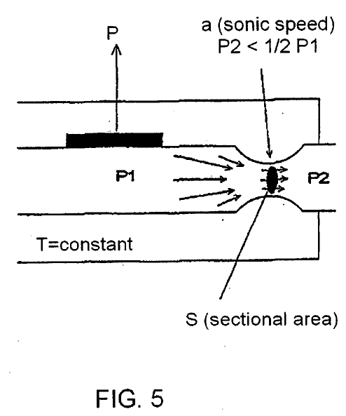

As described above, in the present invention, a source gas flow can be controlled by (a) storing a liquid material in a reservoir; (b) gasifying the liquid material in the reservoir to produce a source gas; (c) passing the source gas through a sonic nozzle to feed the source gas into a chamber; (d) detecting a pressure upstream of the sonic nozzle; and (e) if the detected pressure is different from a set-point pressure, adjusting flow of the source gas upstream of the sonic nozzle to compensate for the difference. Calibration of small mass flow rates of gas using a sonic nozzle is described in “Flow Mass. Instrum., Vol.7, No. 2, pp. 77-83, 1996,” the disclosure of which is incorporated herein by reference. Calibration of gas flow rates involves many parameters and uncertainties. However, if all conditions remain constant, one-to-one correspondence can be established between mass flow (Qm) and pressure (P) upstream of the sonic nozzle. FIG. 5 shows the principle of this relationship.

Qm (kg/sec) is expressed as follows:

Qm=S.a.ρ, wherein S: sectional area of venturi throat (m²), a: sonic speed at venturi throat (m/sec), ρ: density at venturi throat (kg/m³) at constant T (temperature).

The sonic speed a can be constant when P2<½P1, wherein P2 is pressure downstream of the sonic nozzle, P1 is pressure upstream of the sonic nozzle. If air flows through the sonic nozzle, a is 330 m/sec. The density ρ is linearly correlated to pressure P (=P1) if the volume is constant and the temperature is constant. Thus, Qm=C·P, wherein C is a constant. Accordingly, by predetermining the relationship between Qm and P through e.g., experiments, one-to-one correspondence between Qm and P can be established in advance. P can be detected with very high responsibility, such as on the order of msec, and fluctuation of P2 is irrelevant. Under constant conditions, Qm can be controlled very effectively by P.

In the present invention, preferably, by comparing the detected pressure P and a set-point pressure for a target mass flow, feedback control can be performed to maintain mass flow. By installing a mass flow control valve upstream of the sonic nozzle and operating the valve by the feedback control, the mass flow can be adjusted effectively to be at the target value constantly. The mass flow control valve can be controlled electronically and calibration can easily be done in accordance with output of the pressure sensor. For example, first, a gas is fed through the sonic nozzle at a known flow rate, an electrical signal is received from the pressure sensor and inputted to a mass flow controller (including the mass flow control valve), and the reading of the mass flow controller is adjusted to indicate the known flow rate by adjusting a mass flow control circuit. In the above, the tested gas need not be the source gas which is actually used for film formation or other final processing, but can be an alternative gas which can be handled easily, such as nitrogen or chlorofluorocarbon gas, as long as there is physico-chemically correlation between the actual source gas and the alternative gas.

In the present invention, the sonic nozzle can be any type configured to render the mass flow of gas passing through the nozzle proportionate to the pressure upstream of the nozzle, which can be tabular member having a bore wherein the pressure upstream of the bore is at least twice the pressure down stream of the bore. In an embodiment, the pressure upstream of the nozzle may be about 40 kPa to about 80 kPa, and the pressure down stream of the nozzle may be about 5 kPa to about 20 kPa.

No restriction is imposed on the type of control system. Preferably, feedback control can be used including on-off control, proportional control, proportional derivative (PD) control, proportional integral derivative (PID) control, or proportional integral control.

The present invention will be explained with respect to preferred embodiments. However, the present invention is not limited to the preferred embodiments.

According to an preferred embodiment, the present invention concerns a source-gas supply apparatus for supplying a source gas into a chamber (e.g., a reactor) through piping in an apparatus (e.g., a plasma enhanced, thermal, or high density plasma CVD apparatus, or any other apparatus using a source gas) for forming a thin film on a substrate (e.g., a semiconductor substrate) or any other purposes. The apparatus may include a liquid tank for temporarily storing a source gas in liquid state and a flow controller connected between the liquid tank and the piping. The flow controller may comprise a flow control valve provided on the liquid tank side, a sonic nozzle provided on the piping side, a pressure sensor provided upstream of the sonic nozzle and a flow control circuit electrically connected to the flow control valve and the pressure sensor. The flow control circuit is characterizable by determining a source gas flow rate based on a source gas pressure detected by the pressure sensor and operating the flow control valve so as to control a source gas flow rate at a given flow rate.

No restriction is imposed on the liquid material, as long as the material is in a liquid state in a reservoir and is in a gas state when passing through the sonic nozzle. The liquid material may preferably have a boiling point in the range of about 20° C. or higher. No restriction is imposed on the upper limit. However, the material may preferably have a boiling point of about 100° C. or lower. When applying the present invention to plasma CVD, by using tetramethylsilane or dimethyldimethoxysilane as a source gas, a silicon carbide film comprising any one of Si/C/H, Si/C/N/H, or Si/C/O/H may be formed.

The source-gas supply apparatus may further comprise a heater for heating the liquid tank, a temperature sensor for measuring a temperature of the liquid tank, and a temperature controller electrically connected to the heater and the temperature sensor. In that case, gas flow control using the sonic nozzle can be accomplished more reliably.

The present invention is preferably applied to a plasma CVD apparatus for forming a thin film on a semiconductor substrate. The apparatus may include a reaction chamber, a susceptor provided inside the reaction chamber and used for placing the semiconductor substrate thereon, a showerhead provided inside the reaction chamber and disposed parallel to and facing the susceptor, a radio-frequency oscillator electrically connected to the showerhead and used for generating at least one type of radio-frequency power, and a source-gas supply apparatus, which is connected to the showerhead through piping and used for supplying a source gas and comprises a liquid tank for temporarily storing the source gas in liquid state and a flow controller connected between the liquid tank and the piping. The flow controller may comprise a flow control valve provided on the liquid tank side, a sonic nozzle provided on the piping side, a pressure sensor provided upstream of the sonic nozzle and a flow control circuit electrically connected to the flow control valve and the pressure sensor. The flow control circuit may be characterized by calculating a source gas flow rate based on a source gas pressure detected by the pressure sensor and operating the flow control valve so as to control the source gas flow rate at a given flow rate.

Specifically, the radio-frequency power may comprise the first radio-frequency power having a frequency of about 13 MHz to about 30 MHz and the second radio-frequency power having a frequency of about 300 kHz to about 500 kHz.

The plasma CVD apparatus may further include an additive-gas supply means connected to the showerhead through the piping and used for supplying an additive gas.

The additive gas may be specifically an inert gas, or an inert gas and ammonia or CO₂. The additive gas can be selected according to the final film, the source gas, the intended use, etc.

Preferred embodiments of the present invention are described with reference to drawings attached, but the invention should not be limited thereto.

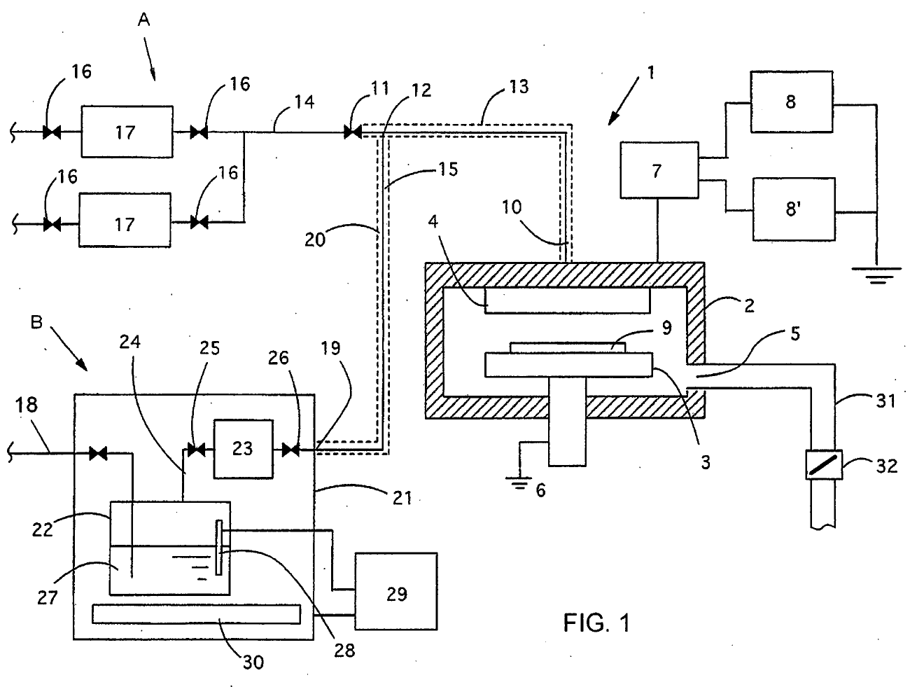

FIG. 1 is a schematic diagram of a preferred embodiment of a plasma CVD apparatus which comprises the source-gas supply apparatus according to the present invention. The plasma CVD apparatus 1 for forming thin films on semiconductor substrates comprises a reaction chamber 2. Inside the reaction chamber, a susceptor 3 for placing the semiconductor substrates 9 on it is provided. The susceptor 3 is made of aluminum alloy and a resistance-heating type sheath heater (not shown in the figure) and a thermocouple (not shown) are laid buried in it. The resistance-heating type sheath heater and the thermocouple are electrically connected to an external temperature controller (not shown); by the temperature controller, a susceptor temperature is controlled at a given value. The susceptor 3 is grounded 6 in order to from one side of electrodes for plasma discharge. A ceramic heater can be used in place of the aluminum alloy susceptor 3. In that regard, the ceramic heater also serves as a susceptor 3 for directly holding a semiconductor substrate 9 inside the reaction chamber. The ceramic heater comprises a ceramic base made by integrally sintering it with a resistance-heating type heater. As a material for the ceramic base, nitride or oxide ceramics resisting fluoride-containing or chlorine-containing species can be used. The ceramic base is composed of preferably aluminum nitride, but can be composed of aluminum oxide or magnesium oxide.

Inside the reaction chamber 2, a showerhead 4 is disposed parallel to and facing the above susceptor 3. In the underside of the showerhead 4, thousands of fine pores (not shown) for emitting a jet of a reaction gas onto a semiconductor substrate 9 are provided. The showerhead 4 is electrically connected to external radio-frequency oscillators 8, 8′ via a matching circuit 7 (an automatic impedance matching box) and serves as the other side of the electrodes. As a modified embodiment, the showerhead 4 is grounded when the susceptor 3 is connected to the radio-frequency power oscillators. The radio-frequency oscillator 8 generates radio-frequency power of 13-30 MHz; the radio-frequency oscillator 8′ generates radio-frequency power of 300-500 kHz. As an alternative embodiment, only the radio-frequency oscillator 8 can be used.

An exhaust port 5 is provided on a side of the reaction chamber 2. The exhaust port 5 is connected to an external vacuum exhaust pump (not shown) through piping 31. A conductance regulating valve 32 for regulating a pressure inside the reaction chamber 2 is provided between the exhaust port 5 and the vacuum pump. The conductance regulating valve 32 is electrically connected to an external pressure controller (not shown). Preferably, a pressure gauge (not shown) for measuring an internal pressure is provided in the reaction chamber 2 and is electrically connected to the pressure controller. The pressure controller operates the conductance regulating valve 32 so as to control a pressure inside the reaction chamber 2 at a given pressure value by responding to a pressure value detected by the pressure gauge. In the above, the electrical connection can be replaced with wireless connection or other types of connection.

Herein, “connected” includes states such as direct connection, indirect connection, physical connection, electrical connection, magnetic connection, electromagnetic connection, wireless connection, functional connection, functional association, etc.

A reaction-gas supply system is provided outside the reaction chamber 2. The reaction-gas supply system comprises a source-gas supply apparatus B and an additive-gas supply means A. The source-gas supply apparatus B and the additive-gas supply means A join together at the junction 12 through piping 15 and piping 14, and subsequently the junction is connected to a gas inlet port of the showerhead 4 through piping 10. At the outer circumference of the piping 15 and the piping 14, heaters 20 and 13 are provided respectively; gases are heated and maintained at a given temperature. A valve 11 is provided on the piping 14.

The additive-gas supply means A has a configuration in which units respectively comprising an additive-gas inlet port, a valve 16 and a flow controller 17 are connected in parallel according to the number of additive gases used. As additive gases, an inert gas, ammonia, CO₂, etc. are used. An additive gas supplied from the inlet port, whose flow rate is controlled by the flow controller 17 through the valve, passes through the piping 14 via the valve 16, and is introduced into the showerhead 4 through the piping 10 via the valve 11.

The source-gas supply apparatus B comprises a housing 21, a liquid tank 22 disposed inside the housing 21 for temporarily storing a source gas 27 in liquid state, and a heater 30 for heating the flow controller 23 connected to the liquid tank 22 and the liquid tank 22. Piping 18 for supplying the liquid source material and piping 19 for drawing a gasified source gas through an inlet port 24 are connected to the liquid tank 22. The flow controller 23 is disposed on the piping 19. A temperature sensor 28 for measuring a temperature inside the liquid tank 22 is provided inside the liquid tank 22. The temperature sensor 28 and the heater 30 are electrically connected to a temperature controller 29 set up outside the housing 21. The temperature of the liquid source gas 27 is maintained at a given value by the temperature controller 29. The liquid source gas 27 used here is an alkoxysilicon compound or an alkylsilicon compound having a relatively low boiling point of about 20° C. to about 100° C. The flow rate of the gasified source gas by the heater 30 is controlled by the flow controller 23 through the piping 19. Subsequently, the source gas is introduced into the showerhead 4 through the piping 15 and the piping 10.

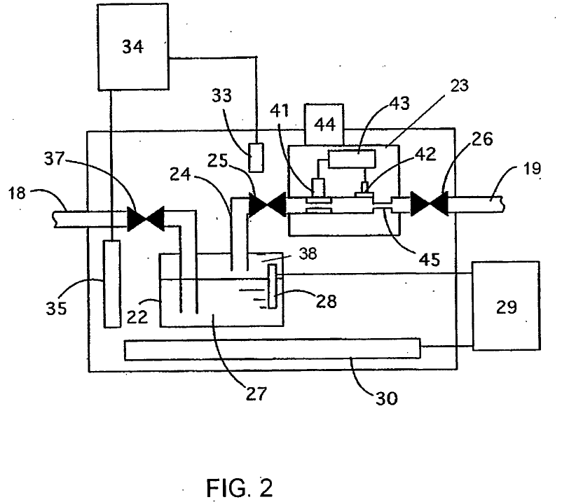

FIG. 2 is an enlarged diagram showing the source-gas supply apparatus B in detail. The same symbols are used for the same members shown in FIG. 1. A heater 35 for heating the inside of the housing and a temperature sensor 33 for measuring a temperature inside the housing are provided inside the housing 21. The heater 35 and the temperature sensor 33 are electrically connected to a temperature controller 34 provided outside the housing; by this temperature controller 34, a temperature inside the housing is controlled. A valve 37 is provided on piping 18. The piping 18 is connected to an external liquid supply apparatus (not shown in the figure). A liquid source material remaining-amount detector (not shown) is provided inside the liquid tank 22, by which a remaining amount of the liquid source material can be detected. By opening the valve 37 based on remaining-amount information, the liquid source material is supplied to the liquid tank 22.

On the upstream and downstream sides of the piping 19 of the flow controller 23, valves 25 and 26 are provided respectively. The flow controller 23 comprises a flow control valve 41 provided in the vicinity of the upstream-side valve 25, a sonic nozzle 45 provided in the vicinity of the downstream-side valve 26, a pressure sensor 42 provided in the vicinity of the sonic nozzle and a flow control circuit 43 electrically connected to the flow control valve 41 and the pressure sensor 42. On the top of the flow controller 23, an electrical signal terminal 44 is provided and is electrically connected to the flow control circuit 43.

The liquid source material 27 stored inside the liquid tank 22 is heated; a part of it is gasified and fills up in the upper room 38 of the liquid tank 22. The gasified source gas is introduced into the flow controller 23 through the piping 19 and via the valve 25; the source gas is introduced into a sonic nozzle 45 via the flow control valve 41. By measuring with the pressure sensor an upstream pressure of the sonic nozzle 34 through which the source gas is passing at sonic speed, a flow rate of the source gas can be calculated.

The flow rate of the source gas is controlled by operating the flow control valve 41 by the flow control circuit 43 so as to match a detected flow rate of the source gas with a design flow rate value. In the plasma CVD apparatus according to the present invention, by transmitting a source gas flow rate which is preset and recorded in the apparatus to the electrical signal terminal 44, a flow rate of the source gas required for thin-film formation is able to be supplied automatically to the reaction chamber 2. The source gas is supplied at a properly controlled flow rate into the piping 15 via the valve 26.

A method for forming silicon carbide films on semiconductor substrates 9 having a diameter of 200 mm using the plasma CVD apparatus 1 according to embodiments of the present invention is described below. The embodiments are not intended to limit the present invention.

A distance between the showerhead 4 and the susceptor 3 (an electrode spacing) is set at about 5 mm to about 100 mm, preferably about 10 mm to about 50 mm, more preferably about 15 mm to about 25 mm. First, a 200 mm semiconductor substrate 9 placed on the susceptor 3 is heated at about 250° C. to about 420° C. (preferably about 300° C. to about 390° C., more preferably about 300° C. to about 370° C.) by the susceptor 3. Simultaneously, the showerhead 4 is heated at about 100° C. to about 300° C. by a heater (not shown) provided at the top of the showerhead 4. About 100 sccm to about 1500 sccm (preferably about 150 sccm to about 800 sccm, more preferably about 200 sccm to about 530 sccm) of tetramethylsilane Si(CH₃)₄ (Boiling point: 26.5° C.), which is an alkylsilicon compound, is introduced from the source-gas supply apparatus B. Simultaneously, from the additive gas supply means A, about 1000 sccm to about 15000 sccm (preferably about 2000 sccm to about 10000 sccm, more preferably about 2500 sccm to about 3000 sccm) of helium is supplied and about 100 sccm to about 1500 sccm (preferably about 200 sccm to about 500 sccm; more preferably about 250 sccm to about 300 sccm) of NH₃ is supplied. At this time, a pressure inside the reaction chamber 2 is maintained at about 200 Pa to about 2660 Pa (preferably at about 400 Pa to about 1000 Pa, more preferably about 600 Pa to about 800 Pa). Subsequently, the first radio-frequency power of about 13 MHz to about 30 MHz at about 300 W to about 1500 W (preferably at about 500 W to about 750 W) and the second radio-frequency power of about 300 kHz to about 500 kHz at about 30 W to about 500 W (preferably at about 50 W to about 150 W) are applied to the showerhead 4. Thus, a plasma chemical reaction takes place in a reaction space inside the reaction chamber, forming a nitrogen-containing silicon carbide film (having Si, C, H as its constituents) on the semiconductor substrate. Additionally, a silicon carbide film (having Si, C, H as its constituents) can be formed using Si(CH₃)₄ and He without adding NH₃.

As films preventing copper diffusion, oxygen-containing silicon carbide films (having Si, C, O, H as its constituents) can be used in place of nitrogen-containing silicon carbide films. When an oxygen-containing silicon carbide film is formed, dimethyldimethoxysilane (DMDMOS ((CH₃)₂Si(OCH₃)₂; a boiling point is 81.4° C.)) is used as a source gas and He is used as an additive gas. Ar can be used in place of He. As an alternative method, Si(CH₃)₄ can be used as a source gas and CO₂, oxygen or N₂O and He can be used as additive gases. In place of He, inert gases such as argon, neon, xenon or krypton or nitrogen gas can be used.

Measurement results of film characteristics under typical film formation conditions are shown below.

A) Examples Using Tetramethylsilane as a Source Gas

### EXAMPLE 1

### Nitrogen-Containing Silicon Carbide Film

Film Formation Conditions:
Si(CH3)4=250 sccm, NH3=250 sccm, He=2500 sccm, pressure 600 Pa, substrate temperature=385° C., 1^{st} RF power 27.12 MHz at 600 W, 2^{nd} RF power 400 kHz at 70 W, electrode spacing=20 mm

Film Characteristic Measurement Results:
Growth rate=100 nm/min., dielectric constant=4.55 (by a mercury probe), film-thickness non-uniformity =±1.8%, refractive index=1.99, film compressive stress=250 MPa, leakage current=5×10⁻⁹ A/cm² (2MV/cm)

### EXAMPLE 2

### Nitrogen-Containing Silicon Carbide Film

Film Formation Conditions:
Si(CH3)4=220 sccm, NH3=250 sccm, He=2600 sccm, pressure 665 Pa, substrate temperature=385° C., 1^{st} RF power 27.12 MHz at 575 W, 2^{nd} RF power 400 kHz at 70 W, electrode spacing=20 mm

Film Characteristic Measurement Results:
Growth rate=100 nm/min., dielectric constant=4.40 (by a mercury probe), film-thickness non-uniformity =±1.6%, refractive index=1.90, film compressive stress=200 MPa, leakage current=2×10⁻⁹ A/cm² (2MV/cm)

### EXAMPLE 3

### Oxygen-Containing Silicon Carbide Film

Film Formation Conditions:
Si(CH3)4=300 sccm, CO2=1900 sccm, He=2500 sccm, pressure 533 Pa, substrate temperature=385° C., 1^{st} RF power 27.12 MHz at 450 W, 2^{nd} RF power 400 kHz at 90 W, electrode spacing=20 mm

Film Characteristic Measurement Results:
Growth rate=200 nm/min., dielectric constant=4.30 (by a mercury probe), film-thickness non-uniformity =±1.2%, refractive index=2.05, film compressive stress=240 MPa, leakage current=5×10⁻⁸ A/cm² (2MV/cm)

B) Examples Using Dimethyldimethoxysilane (DMDMOS) as a Source Gas

### EXAMPLE 4

### Oxygen-Containing Silicon Carbide Film

Film Formation Conditions:
DMDMOS=140 sccm, He=50 sccm, pressure 560 Pa, substrate temperature=385° C., 1^{st} RF power 27.12 MHz at 1500 W, electrode spacing=24 mm

Film Characteristic Measurement Results:
Growth rate=540 nm/min., dielectric constant=2.85 (by a mercury probe), film-thickness non-uniformity=±1.1%, refractive index=1.43, film tensile stress=55 MPa

### EXAMPLE 5

### Oxygen-Containing Silicon Carbide Film

Film Formation Conditions:
DMDMOS=100 sccm, He=73 sccm, pressure 560 Pa, substrate temperature=385° C., 1^{st} RF power 27.12 MHz at 1300 W, electrode spacing=24 mm

Film Characteristic Measurement Results:
Growth rate=430 nm/min., dielectric constant=2.95 (by a mercury probe), film-thickness non-uniformity =±1.6%, refractive index=1.43, film tensile stress=50 MPa

By using the plasma CVD apparatus having the source-gas supply apparatus according to the present invention, silicon carbide films were able to be formed at rates of 100 nm or more per minute, and low dielectric constants of about 4.0 to about 5.0 were able to be achieved. When DMDMOS was used as a source gas, oxygen-containing silicon carbide films having dielectric constants of below about 3.0 were able to be formed. Additionally, film-thickness non-uniformity on one semiconductor substrate (a value which is obtained by dividing a difference between the maximum value and the minimum value by ½ of the mean value is expressed in percentage) of ±3% or less with the representative value of ±1.5% was able to be obtained.

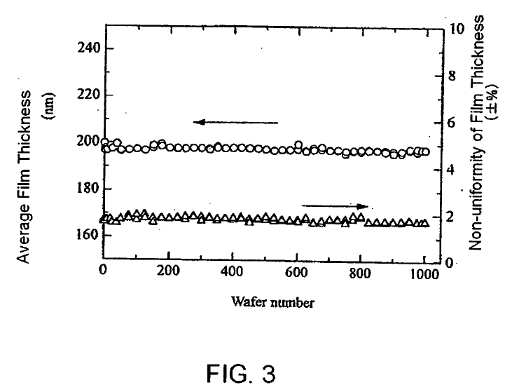

FIG. 3 shows film thickness measurement results of grown films when nitrogen-containing silicon carbide films were formed on 1000 pieces of silicon substrates with a diameter of 200 mm consecutively using Si(CH₃)₄ as a source gas and ammonia and He as additive gases. As seen from the graph, film thickness reproducibility of grown films was ±0.99% which was remarkably excellent. This means that a constant amount of the reaction gas was always supplied to the substrates.

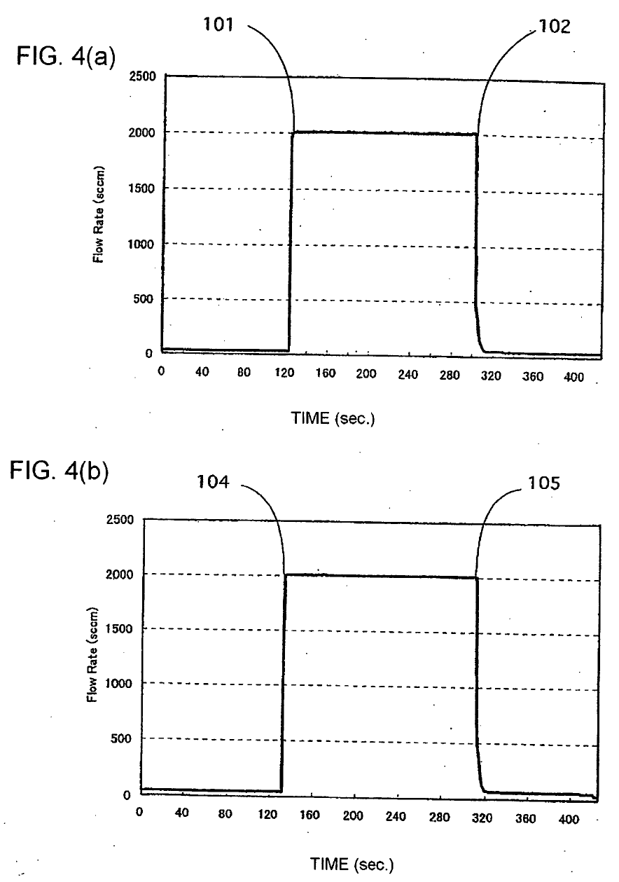

FIGS. 4(a) and 4(b) show flow rate controllability of the source-gas supply apparatus. FIG. 4(a) shows the flow rate controllability when a temperature of the liquid tank 22 was set at 25° C. and Si(CH₃)₄ was generated at flow rate of 2 liters per minute (2 liters or 2000 sccm of the gas under 0° C. and 1 atom conditions). In the above, the 2000 sccm was calculated from molality of the liquid flowing into the tank which was heated, vaporized, and raised the pressure in the tank (gas was forced to pass through the nozzle). Also, the flow controller was previously tuned up to adjust the opening of the flow control valve to maintain the pressure corresponding to 2000 sccm under the same conditions. The flow controller was calibrated to indicate 2000 sccm when receiving a signal of the corresponding pressure. The flow rates indicated in FIGS. 4(a) and (b) were the readings of the flow controller.

Gas generation was started by opening the valves 25 and 26 and setting a flow rate at the flow controller 23 (at 2 litters per minute) at the point of source gas supply start 101. Before the point of source gas supply start 101, the pressure inside the liquid tank 22 was 106 kPa. Simultaneously when the valves 25 and 26 were shut off at the point of gas supply stop, the flow rate at the flow controller 23 was set at 0.0 sccm and gas supply was stopped. The gas pressure inside the liquid tank 22 immediately before the point of gas supply stop 102 was 81 kPa. The flow rates with time were shown in FIG. 4(a).

As shown in the graphs in FIG. 4(a), it is seen that the gas flow rate controlled and its controllability were not changed and were stable even when a source gas pressure was changed. In FIG. 4(a), although the gas pressure which was 106 kPa at the point of gas supply start decreased to 81 kPa after approximately 3 minutes, the supplied flow rate remained constant and was stable. This was because as the pressure inside the tank decreased, the pressure sensor detected a reduction of pressure and sent a signal to the flow control valve which then opened the opening to compensate for the reduction of the pressure, thereby successfully maintaining the pressure upstream of the sonic nozzle. This means that the flow rate could remain constant as shown in FIG. 4(a).

The flow control valve started with a reduced opening so that the pressure upstream of the sonic nozzle could be maintained at a constant value in the range of 40-80 kPa which was lower than the pressure inside the tank (106 kPa) but at least twice the pressure downstream of the sonic nozzle (5-20 kPa). As the pressure inside the tank decreased, the flow control valve gradually opened its opening in accordance with a signal from the pressure sensor so that the pressure upstream of the sonic nozzle could be maintained at a constant value in the range of 40-80 kPa, despite the fact that the pressure inside the tank decreased to 81 kPa.

Although the graph shown in FIG. 4(a) is in fact constituted by ripples which triggered feedback control, because responsibility of the pressure sensor was high (on the order of msec), ripples were controlled to have small amplitude which could not be recognized in FIG. 4(a) and could be considered to be substantially constant.

Incidentally, before the point of gas start 101 and after the point of gas stop 102, the flow rate does not indicate zero. This is because the flow rate was determined using the flow controller 23 based on the pressure upstream of the sonic nozzle, and even if no gas flowed through the nozzle, the pressure sensor picked up the presence of gas remaining in the piping, causing false reading of the flow.

FIG. 4(b) shows the flow rate controllability when a temperature of the liquid tank 22 was set at 35° C. and Si(CH₃)₄ was generated at flow rate of 2 liters per minute (2 liters or 2000 sccm of the gas under 0° C. and 1 atom conditions). The flow controller was calibrated for the above conditions. Gas generation was started by opening the valves 25 and 26 and setting a flow rate at the flow controller 23 (at 2 litters per minute) at the point of source gas supply start 104. Before the point of source gas supply start 104, the pressure inside the liquid tank 22 was 145 kPa. The flow control valve relatively closed its opening in order to maintain the pressure upstream of the sonic valve at a constant value in the range of 40-70 kPa. Simultaneously when the valves 25 and 26 were shut off at the point of gas supply stop 105, a flow rate at the flow controller 23 was set at 0 sccm and gas supply was stopped. The gas pressure inside the liquid tank 22 immediately before the point of gas supply stop 105 was about 70 kPa. The flow control valve gradually opened its opening in order to maintain the pressure upstream of the sonic valve at a constant value in the range of 40-70 kPa, despite the fact that the pressure inside the tank decreased to about 70 kPa. FIG. 4(b) shows similar or same excellent effects as in FIG. 4(a).

In comparison with FIGS. 4(a) and 4(b), it is seen that there was no difference in flow rate controllability between when the gas pressure was 106 kPa (FIG. 4(a)) and when the gas pressure was 145 kPa (FIG. 4(b)) and that constant control can be realized even if a gas pressure is changed.

The present invention includes the above mentioned embodiments and other various embodiments including the following:

1) A source-gas supply apparatus for supplying a source gas into a reaction chamber through piping in a plasma CVD apparatus for forming a thin film on a semiconductor substrate, which comprises a liquid tank for temporarily storing a source gas in liquid state and a flow controller connected between said liquid tank and said piping, wherein said flow controller comprises a flow control valve provided on the liquid tank side, a sonic nozzle provided on the piping side, a pressure sensor provided upstream of said sonic nozzle and a flow control circuit electrically connected to said flow control valve and said pressure sensor; said flow control circuit is characterized in that calculating a source gas flow rate based on a source gas pressure detected by said pressure sensor and operating said flow control valve so as to control said source gas flow rate at a given flow rate.

2) The source-gas supply apparatus according to Item 1), wherein said source gas has a boiling point in the range of about 20° C. to about 100° C.

3) The source-gas supply apparatus according to Item 2), wherein said source gas is an alkoxysilicon compound.

4) The source-gas supply apparatus according to Item 2), wherein said source gas is an alkylsilicon compound.

5) The source-gas supply apparatus according to Item 1), which further comprises a heater for heating said liquid tank, a temperature sensor for measuring a temperature of said liquid tank and a temperature controller electrically connected to said heater and said temperature sensor.

6) A plasma CVD apparatus for forming a thin film on a semiconductor substrate, which comprises a reaction chamber, a susceptor provided inside said reaction chamber and used for placing said semiconductor substrate thereon, a showerhead provided inside said reaction chamber and disposed parallel to and facing said susceptor, a radio-frequency oscillator electrically connected to said showerhead and used for generating at least one type of radio-frequency power, and a source-gas supply apparatus, which is connected to said showerhead through piping and used for supplying a source gas and comprises a liquid tank for temporarily storing the source gas in liquid state and a flow controller connected between said liquid tank and said piping, in which said flow controller comprises a flow control valve provided on the liquid tank side, a sonic nozzle provided on the piping side, a pressure sensor provided upstream of said sonic nozzle and a flow control circuit electrically connected to said flow control valve and said pressure sensor; said flow control circuit is characterized in that calculating a source gas flow rate based on a source gas pressure detected by said pressure sensor and operating said flow control valve so as to control said source gas flow rate at a given flow rate.

7) The plasma CVD apparatus according to Item 6), wherein said source gas has a boiling point in the range of 20-100° C.

8) The plasma CVD apparatus according to Item 7), wherein said source gas is an alkoxysilicon compound.

9) The plasma CVD apparatus according to Item 7), wherein said source gas is an alkylsilicon compound.

10) The plasma CVD apparatus according to Item 6), wherein said source-gas supply apparatus further comprises a heater for heating said liquid tank, a temperature sensor for measuring a temperature of said liquid tank and a temperature controller electrically connected to said heater and said temperature sensor.

11) The plasma CVD apparatus according to Item 6), wherein said radio-frequency power has a frequency of 1.3-30 MHz.

12) The plasma CVD apparatus according to Item 6), wherein said radio-frequency power comprises the first radio-frequency power having a frequency of 13-30 MHz and the second radio-frequency power having a frequency of 300-500 kHz.

13) The plasma CVD apparatus according to Item 6), which further comprises an additive-gas supply means connected to said showerhead through said piping and used for supplying an additive gas.

14) The plasma CVD apparatus according to Item 13), wherein said additive gas is an inert gas.

15) The plasma CVD apparatus according to Item 13), wherein said additive gas is an inert gas and ammonia.

16) The plasma CVD apparatus according to Item 13), wherein said additive gas is an inert gas and carbon dioxide, oxygen or N₂O.

17). The plasma CVD apparatus according to Item 14), wherein said thin film is a silicon carbide film.

18) The plasma CVD apparatus according to Item 17), wherein said silicon carbide film is characterized in that comprising Si, C and H.

19) The plasma CVD apparatus according to Item 15), wherein said thin film is a nitrogen-containing silicon carbide film.

20) The plasma CVD apparatus according to Item 19), wherein said nitrogen-containing silicon carbide film is characterized in that comprising Si, C, N and H.

21) The plasma CVD apparatus according to Item 16), wherein said thin film is an oxygen-containing silicon carbide film.

22) The plasma CVD apparatus according to Item 21), wherein said oxygen-containing silicon carbide film is characterized in that comprising Si, C, O and H.

23) The plasma CVD apparatus according to any one of Items 17) to 22), wherein said thin film is characterized in that being formed using tetramethylsilane Si(CH₃)₄ as a source gas.

24) The plasma CVD apparatus according to Items 21) or 22), wherein said thin film is characterized in that being formed using dimethyldimethoxysilane as a source gas.

The present application claims priority to Japanese Patent Application No. 2003-304501, filed Aug. 28, 2003, the disclosure of which is incorporated herein by reference in its entirety.

It will be understood by those of skill in the art that numerous and various modifications can be made without departing from the spirit of the present invention. Therefore, it should be clearly understood that the forms of the present invention are illustrative only and are not intended to limit the scope of the present invention.

1. A source-gas supply apparatus for supplying a source gas into a CVD reactor, which comprises:
a reservoir for storing a liquid material having an inlet port through which the liquid material is introduced and an outlet port through which a source gas gasified from the liquid material is discharged, said reservoir being provided with a heater;
a gas flow path connected the reservoir and the CVD reactor;
a sonic nozzle disposed in the gas flow path, through which the source gas is introduced into the CVD reactor;
a pressure sensor disposed in the gas flow path upstream of the sonic nozzle;
a flow control valve disposed in the gas flow path upstream of the pressure sensor; and
a flow control circuit which receives a signal from the pressure sensor and outputs a signal to the flow control valve to adjust opening of the flow control valve as a function of the signal from the pressure sensor.

2. The source-gas supply apparatus according to claim 1, wherein the flow control circuit includes a feedback control system which adjusts the opening of the flow control valve to maintain a set-point mass flow rate based on the detected pressure.

3. The source-gas supply apparatus according to claim 1, further comprising a housing which encloses the reservoir, the sonic nozzle, the pressure sensor, and the flow control valve.

4. The source-gas supply apparatus according to claim 3, further comprising a temperature controller, wherein the housing is provided with a temperature sensor, and the temperature controller controls the temperature inside the housing.

5. The source-gas supply apparatus according to claim 1, further comprising a temperature controller, wherein the reservoir includes a temperature sensor, and the temperature controller controls the temperature inside the reservoir.

6. The source-gas supply apparatus according to claim 1, wherein the gas flow path further comprises a shutoff valve downstream of the sonic valve and a shutoff valve upstream of the flow control valve.

7. The source-gas supply apparatus according to claim 1, wherein the reservoir contains an alkoxysilicon compound or an alkylsilicon compound.

8. The source-gas supply apparatus according to claim 1, wherein the gas flow path is enclosed by a heating element.

9. A CVD apparatus comprising:
a reactor for forming a thin film on a semiconductor substrate;
the source-gas supply apparatus of claim 1 which is connected to the reactor; and
an additive gas supply apparatus connected to the reactor, to supply an additive gas into the reactor.

10. The CVD apparatus according to claim 9, further comprising a radio-frequency (RF) oscillator to supply RF power to the reactor.

11. The CVD apparatus according to claim 9, wherein the source-gas supply apparatus further comprises a housing which encloses the reservoir, the sonic nozzle, the pressure sensor, and the flow control valve.

12. The CVD apparatus according to claim 11, wherein the gas flow path between the reactor and the housing is enclosed by a heating element.

13. A method for controlling a source gas flow, comprising:
storing a liquid material in a reservoir;
gasifying the liquid material in the reservoir to produce a source gas;
passing the source gas through a sonic nozzle to feed the source gas into a CVD reactor;
detecting a pressure upstream of the sonic nozzle; and
if the detected pressure is different from a set-point flow rate, adjusting flow of the source gas upstream of the sonic nozzle to maintain the flow at the set-point flow rate.

14. The method according to claim 13, wherein a pressure upstream of the sonic nozzle is set at least twice a pressure downstream of the sonic nozzle.

15. The method according to claim 13, wherein an environment surrounding the sonic nozzle is controlled at a pre-selected temperature.

16. The method according to claim 13, wherein the reservoir is controlled at a pre-selected temperature.

17. The method according to claim 13, wherein the liquid material has a boiling point in the range of about 20° C. to about 100° C.

18. The method according to claim 13, wherein the liquid material is an alkoxysilicon compound or an alkylsilicon compound.

19. A method for controlling a source gas flow, comprising:
storing an alkoxysilicon compound or an alkylsilicon compound as a liquid material in a reservoir;
gasifying the liquid material in the reservoir to produce a source gas;
passing the source gas through a sonic nozzle to feed the source gas into a chamber;
detecting a pressure upstream of the sonic nozzle; and
if the detected pressure does not correspond to a set-point flow rate, adjusting flow of the source gas upstream of the sonic nozzle to maintain the flow at the set-point flow rate.

20. A method of thin film formation, comprising:
supplying the source gas into a reactor by the method of claim 13;
supplying an additive gas into the reactor; and
forming a thin film on a semiconductor substrate placed in the reactor by CVD.

21. The method according to claim 20, further comprising supplying radio-frequency (RF) power to the reactor.

22. The method according to claim 21, wherein the additive gas is an inert gas.

23. The method according to claim 21, wherein the additive gas is an inert gas and ammonia.

24. The method according to claim 21, wherein the additive gas is an inert gas and carbon dioxide, oxygen or N₂O.

25. The method according to claim 21, wherein the thin film is a silicon carbide film.

26. The method according to claim 20, wherein the liquid material is tetramethylsilane or dimethyldimethoxysilane.
